(19) United States
(12) Patent Application Publication
(10) Pub. No.: US 2026/0239944 A1
(43) Pub. Date: Aug. 13, 2026

(54) DESIGN/TOPOGRAPHY BASED Z-HEIGHT & OPTICAL PROXIMITY CORRECTION (OPC) OPTIMIZATION & CO-OPTIMIZATION

(71) Applicant: TOKYO ELECTRON LIMITED, Tokyo (JP)

(72) Inventors: David POWER, Albany, NY (US); David CONKLIN, Saratoga Springs, NY (US); Jodi GRZESKOWIAK, Schenectady, NY (US)

(73) Assignee: TOKYO ELECTRON LIMITED, Tokyo (JP)

(21) Appl. No.: 19/049,183

(22) Filed: Feb. 10, 2025

(51) Int. Cl. H01L 21/768

(52) U.S. Cl. CPC H10W 20/062

(57) ABSTRACT

Aspects of the present disclosure provide an optical proximity correction (OPC) process that is performed with typical process variations for lithography taken into consideration. For example, the method can include providing a nominal condition for a substrate, updating the nominal condition based on topography of the substrate, determining a process window (PW) condition based on the updated nominal condition, performing nominal and PW simulations based on the updated nominal and PW conditions, and performing optical proximity correction (OPC) verification checks at the updated nominal and PW conditions to identify hotspots of the substrate.

### FIELD OF THE INVENTION

The present disclosure relates to semiconductor processing, and, in particular, to optical proximity correction (OPC) that takes into account topography variations.

### BACKGROUND

The background description provided herein is for the purpose of generally presenting the context of the disclosure. Work of the presently named inventors, to the extent the work is described in this background section, as well as aspects of the description that may not otherwise qualify as prior art at the time of filing, are neither expressly nor impliedly admitted as prior art against the present disclosure.

Optical proximity correction (OPC) Verification is important to identify the critical wafer hotspots prior to mask fabrication. It helps to identify process limiting structures and possible yield limiters. These hotspots are also used by litho-engineers to set up process conditions upfront. OPC Verification generally involves verification done at nominal and process window conditions. The process window conditions take into consideration typical process variations for lithography. In this standard flow, the post chemical-mechanical polishing/planarization (CMP) topography variation was also lumped into these process variations via focus. But in current technologies especially in higher metal layers, CMP induced topography variation has become a major contributor to limit the overall process window. This results in different best focus for structures with different topography.

### SUMMARY

Aspects of the present disclosure provide an optical proximity correction (OPC) process that is performed with typical process variations for lithography taken into consideration. For example, the method can include providing a nominal condition for a substrate, updating the nominal condition based on topography of the substrate, determining a process window (PW) condition based on the updated nominal condition, performing nominal and PW simulations based on the updated nominal and PW conditions, and performing OPC verification checks at the updated nominal and PW conditions to identify hotspots of the substrate.

In an embodiment, the method can further include calculating topography induced focus shift based on the topography of the substrate, wherein the nominal condition can include a nominal focus maintained in a lithography process, and updating the nominal condition can include adding the topography induced focus shift to the nominal condition. In another embodiment, the method can further include performing a topography simulation across the substrate to calculate the topography of the substrate.

In an embodiment, the nominal condition can include a nominal dose, and the PW condition can include variations in dose relative to the nominal dose. In another embodiment, the nominal condition can include a nominal focus, and the PW condition can include a PW focus relative to the nominal focus. In some embodiments, the nominal condition can include a nominal mask bias, and the PW condition can include a mask bias offset relative to the nominal mask bias.

In some embodiments, the method can further include forming a dielectric material on the substrate within a first region to form one or more first dielectric layers that are spaced from one another, forming a first height correction layer on a first one of the first dielectric layers, the first height correction layer having a first height that is determined based on the topography of the substrate within the first region, depositing a conductive material on the substrate to fill one or more first trenches surrounded by the first dielectric layers and the first height correction layer and cover the first dielectric layers and the first height correction layer, and performing a planarization process to planarize the conductive material and the first height correction layer until uncovering the first dielectric layers.

In an embodiment, the method can further include forming a second height correction layer on a second one of the first dielectric layers, the second one of the first dielectric layers being closer than the first one of the first dielectric layers to a center of the first region and having a second height that is greater than the first height of the first one of the first dielectric layers. In another embodiment, the first height of the first height correction layer can be varied and increases toward a center of the first region. In some embodiments, the method can further includes forming the dielectric material on the substrate within a second region to form one or more second dielectric layers that are spaced from one another, depositing the conductive material on the substrate to fill one or more second trenches surrounded by the second dielectric layers and cover the second dielectric layers, and performing the planarization process to planarize the conductive material until uncovering the second dielectric layers, wherein the topography of the substrate within the second region can be different from the topography of the substrate within the first region. In various embodiments, the method can further include forming a second height correction layer on one of the second dielectric layers, the second height correction layer having a second height that is determined based on the topography of the substrate within the second region, the second height being different from the first height, wherein depositing the conductive material on the substrate to fill the second trenches surrounded by the second dielectric layers and cover the second dielectric layers can include depositing the conductive material on the substrate to fill the second trenches surrounded by the second dielectric layers and the second height correction layer and cover the second dielectric layers and the second height correction layer, and performing the planarization process to planarize the conductive material until uncovering the second dielectric layers includes performing the planarization process to planarize the conductive material and the second height correction layer until uncovering the second dielectric layers.

In an embodiment, the conductive material and the first height correction layer can be polished when the planarization process is performed. In another embodiment, the planarization process can be a chemical-mechanical polishing/planarization (CMP) process. In some embodiments, the conductive material can include cupper (Cu) or tungsten (W). In various embodiments, the dielectric material can be formed on the substrate in a spin-on film deposition process.

Note that this summary section does not specify every embodiment and/or incrementally novel aspect of the present disclosure or claimed invention. Instead, this summary only provides a preliminary discussion of different embodiments and corresponding points of novelty. For additional details and/or possible perspectives of the invention and embodiments, the reader is directed to the Detailed Description section and corresponding figures of the present disclosure as further discussed below.

### BRIEF DESCRIPTION OF THE DRAWINGS

Various embodiments of this disclosure that are proposed as examples will be described in detail with reference to the following figures, wherein like numerals reference like elements, and wherein:

FIG. 1 shows a simple CMP model simulation flow;

FIG. 2 shows a flow chart of a conventional OPC Verification method;

FIG. 3 shows a flow chart of a topography aware OPC Verification method according to some embodiments of the present disclosure;

FIG. 4 shows a process weakpoint structure that is is identified by the topography aware OPC Verification method;

FIGS. 5A and 5B show the same weakpoint in the conventional OPC Verification method and in the topography aware OPC Verification method;

FIGS. 6A-6C illustrate an intermediate step of a method of fabricating a semiconductor structure after a conductive material is deposited to fill spaces surrounded by a dielectric material and planarized to form first and second metal lines;

FIGS. 7A and 7B illustrate an intermediate step of an exemplary method of fabricating a semiconductor structure after a conductive material is deposited to fill spaces surrounded by a dielectric material and planarized to form first and second metal lines according to some embodiments of the present disclosure;

FIGS. 8A-8E illustrate a method of form a height correction layer according to some embodiments of the present disclosure;

FIG. 9 shows the thicknesses (uniformness) across a surface (e.g., measured in X axis) of three different dielectric layers prior to and after CMP;

FIGS. 10A and 10B show the topologies of a semiconductor structure that includes one or more dielectric layers coated with a height correction layer that is not corrected with respect to its height prior to and after CMP, respectively;

FIG. 10C shows the topology of a semiconductor structure that includes one or more dielectric layers coated with a height correction layer that is corrected with respect to its height based on the pattern density or topography of a region within which the dielectric layers are located after CMP;

FIG. 11 is a flow chart of an exemplary method for patterning for CMP iso-dense bias compensation using z-height according to some embodiments of the present disclosure; and

FIG. 12 shows a system that combines the CMP model simulation flow, the topography aware OPC Verification method, the intermediate steps of the exemplary method of fabricating the semiconductor structure and the exemplary method for patterning for CMP iso-dense bias compensation using z-height to a semiconductor structure according to some embodiments of the present disclosure.

### DETAILED DESCRIPTION

The following disclosure provides many different embodiments, or examples, for implementing different features of the provided subject matter. Specific examples of components and arrangements are described below to simplify the present disclosure. These are, of course, merely examples and are not intended to be limiting. For example, the formation of a first feature over or on a second feature in the description that follows may include embodiments in which the first and second features are formed in direct contact, and may also include embodiments in which additional features may be formed between the first and second features, such that the first and second features may not be in direct contact. In addition, the present disclosure may repeat reference numerals and/or letters in the various examples. This repetition is for the purpose of simplicity and clarity and does not in itself dictate a relationship between the various embodiments and/or configurations discussed. Further, spatially relative terms, such as “top,” “bottom,” “beneath,” “below,” “lower,” “above,” “upper” and the like, may be used herein for ease of description to describe one element or feature's relationship to another element(s) or feature(s) as illustrated in the figures. The spatially relative terms are intended to encompass different orientations of the device in use or operation in addition to the orientation depicted in the figures. The apparatus may be otherwise oriented (rotated 90 degrees or at other orientations) and the spatially relative descriptors used herein may likewise be interpreted accordingly.

The order of discussion of the different steps as described herein has been presented for clarity sake. In general, these steps can be performed in any suitable order. Additionally, although each of the different features, techniques, configurations, etc. herein may be discussed in different places of this disclosure, it is intended that each of the concepts can be executed independently of each other or in combination with each other. Accordingly, the present invention can be embodied and viewed in many different ways.

In the present semiconductor foundry technologies, with aggressive design rule shrinks, process margins have considerably reduced. Lithography and resolution enhancement technique (RET) has emerged as one of the most important steps in chip fabrication. OPC and other RET steps are performed on the incoming design to ensure that it is manufacturable. OPC Verification is performed on the post OPC layout to identify critical lithography hotspots, which might be process delimiters and possible yield limiters.

Most of the steps in the fabrication flow create non-planar surfaces which can affect the later stages of patterning. Chemical-mechanical polishing/planarization (CMP) is one of the most important steps used to achieve planarization. But due to layout pattern density dependent variation, CMP cannot achieve the required level of planarization. This result in topography variation which affects the next layer's patterning. Traditional OPC variation does not take this into account and does not predict the real hotspots. According to the present disclosure, a method is proposed to use this topography information in the OPC Verification flow to predict the real critical hotspots.

CMP is an essential process for wafer surface planarization. CMP process variations became more complex in advanced process nodes. CMP is a necessary step to bring the entire wafer surface within the depth of focus of a photolithography system. As the number of layers and chip design complexity increases, the difficulty in maintaining the focus in lithography process increases.

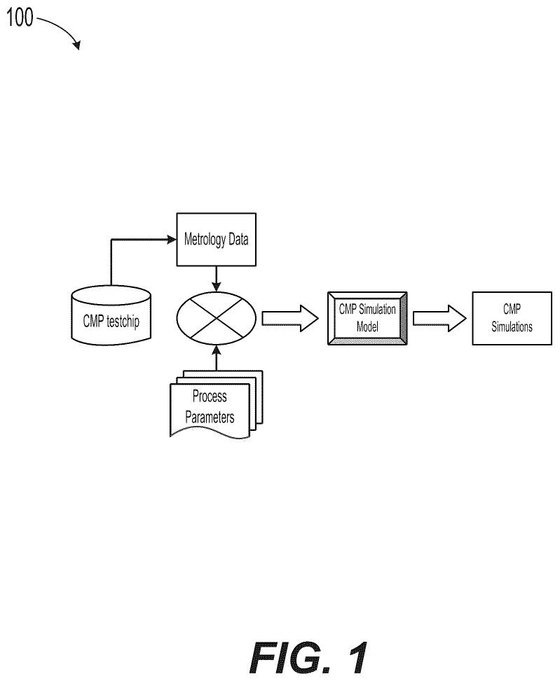

Silicon calibrated CMP model helps to early predict and fix CMP hotspots and CMP induced lithography weakpoints. FIG. 1 shows a simple CMP model simulation flow 100. 28 nm CMP model has been developed using metrology data collected at electrochemical deposition step and for all critical CMP steps. CMP model also accounts for the physical characteristics like pad property, pressure and polish times. CMP model needs to be accurately predicting both global and local topography variations in the process.

Conventional OPC and optical rule checking (ORC) verification consider critical patterns on an ideal planar surface but in reality, pattern density variations in the design leads to uneven surface topography variation which may inject printability variations. For example, critical structures/weakpoints falling on a higher or lower topography surface tend to bridge or pinch due to topography driven lithography focus variations.

OPC and other RET steps are performed on the incoming design to make sure that the pattern is manufacturable and close to the intended design across a certain process variation.

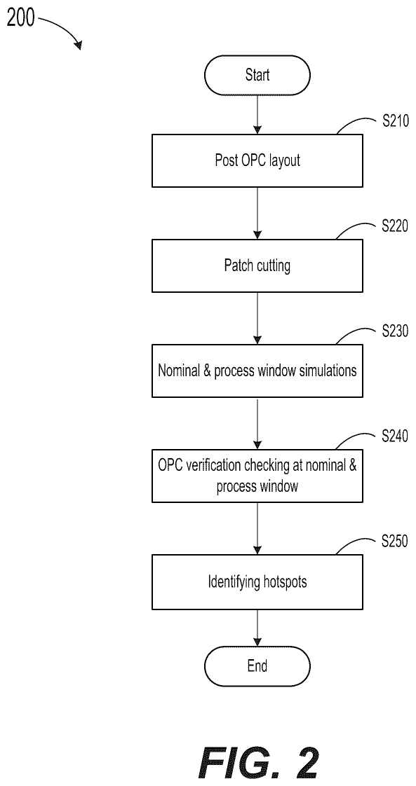

In a conventional OPC Verification method 200, as shown in FIG. 2, post OPC layout (e.g., at step S210) can be divided into several patches representing distinct regions of the layout (e.g., at step S220). This patch cutting combined with parallel processing enables the OPC Verification to be significantly accelerated. For each patch, nominal & process window (PW) simulations are then performed (e.g., at step S230). The process window conditions typically have variations in dose (relative to nominal dose), focus (relative to nominal focus) and mask bias offsets. These conditions are chosen to cover the variability expected from a High Volume Manufacturing process (disclosed by Andre Poock et al., “OPC hotspot identification challenges: ORC vs. PWQ on wafer”, Proc. SPIE 7122, Photomask Technology 2008, 71220Y (Oct. 17, 2008), which is incorporated herein by reference in its entirety).

One of the basic assumptions is that this variability is random and centered around the nominal condition. OPC Verification checks (bridging, necking, via coverage etc. ,) are performed (e.g., at steps S240) on these simulations to identify the critical hotspots (e.g., at steps S250). Inherent density variations in the design impact CMP polish rate. This result in topography variations post CMP, which in turn adds a systematic offset to the focus for the affected area. The conventional OPC Verification method 200 does not account for the topography variations and ends up not highlighting the real critical wafer hotspots.

The process window conditions take into consideration typical process variations for lithography. In this standard flow, the post chemical-mechanical polishing/planarization (CMP) topography variation was also lumped into these process variations via focus. But in current technologies especially in higher metal layers, CMP induced topography variation has become a major contributor to limit the overall process window. This results in different best focus for structures with different topography.

This gives rises to requirement of OPC Verification method taking into account these location-specific variations in order to know if the mask data can be used or not. According to the present disclosure, a method is proposed to incorporate the topography induced focus shift into the OPC Verification flow. OPC Verification checks are performed at the new nominal and process window conditions to identify the real hotspots seen on wafer. Results are shown where the highlighted hotspots with the proposed new flow correlate better with wafer results. Runtime was also taken into consideration when the flow was developed. Experiments on various products show better accuracy with minimal runtime impact.

Due to narrow process margin in the present node shrinkage conditions, critical structures/weakpoints found through ORC help the litho-engineers to a great extent in setting up the process conditions upfront. It is very important that these weakpoints correlate better to the real fab weakpoints for a better process centering. In the present technologies, especially in higher metal layers, post CMP topography variations have become one of the major contributors to weakpoints. These topography variations have been found to impact the best focus of each structure in a chip. The post CMP topography variations are found to be more local (with small radius of impact) which cannot be corrected by the scanner.

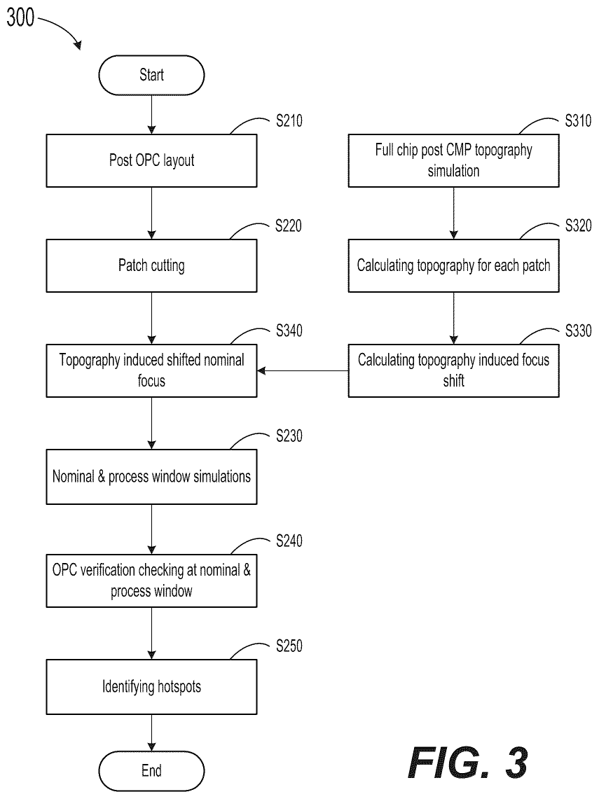

To solve this problem, a novel (topography aware) OPC Verification method 300 (shown in FIG. 3) is proposed where CMP induced topography variations are taken into account. The OPC Verification method 300 can involve performing post CMP topography simulations across the full chip (e.g., at step S310). For each patch, the topography, which may be output from the CMP model simulation flow 100, and, accordingly, topography induced focus shift can be calculated (e.g., at steps S320 and S330, respectively). This focus shift can be added to the nominal focus to get the new nominal focus (e.g., at step S340). The process window conditions can thus be calculated relative to the new nominal focus (e.g., at step S230). OPC Verification checks can be performed at the new nominal and process window conditions to identify hotspots (e.g., at step S240). The runtime impact can be kept minimal by adding one constant focus offset (e.g., the focus shift calculated at step S330) per simulation patch. With this new approach, new corridors are opened even for DFM/OPC for fixing the topography related weakpoints prior to tapeouts.

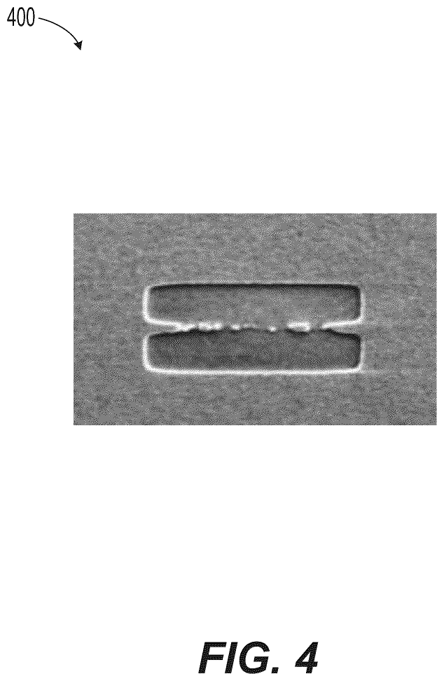

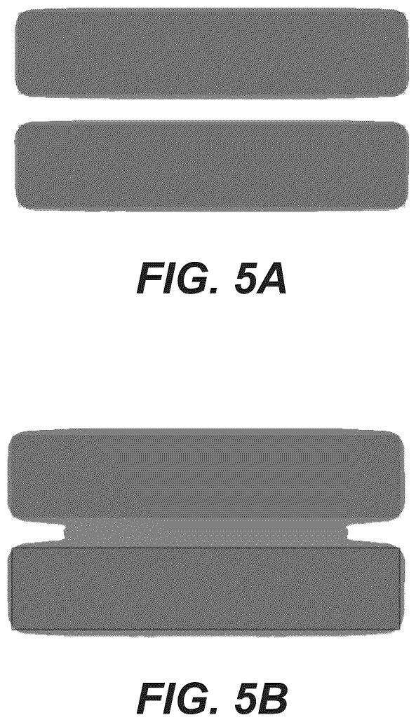

In FIG. 4, a process weakpoint structure 400 is identified by the topography aware OPC Verification method 300 on the wafer which is, however, not highlighted by the standard OPC Verification checks (e.g., step S250 performed in the conventional OPC Verification method 200). This hotspot was found to be present on high topography region. When the same full chip was run through the topography aware OPC Verification method 300, this hotspot was highlighted as a critical weakpoint. FIGS. 5A and 5B show the same weakpoint in the conventional OPC Verification method 200 and in the topography aware OPC Verification method 300, respectively.

Experiments were made on various products to verify that the topography aware OPC Verification method 300 can highlight the real weakpoints seen on wafer without flagging false hotspots. On a product at a metal layer, the focus exposure matrix (FEM) results of the weakpoints highlighted by the conventional OPC Verification method 200 do not show weakpoints that have any issue across FEM. By contrast, the FEM results of the weakpoints highlighted by the topography aware OPC Verification method 300 tend to pinch at a higher positive defocus. This shows that topography aware OPC Verification method 300 highlights more relevant weakpoints on wafer when compared to conventional OPC Verification method 200.

The exact prediction of this approach depends on the quality of the OPC and CMP models and how well the models are calibrated and validated for the current inline processes. Any one of the model's inaccuracies or any process changes if not properly updated and validated in the model may lead to false hotspots.

Importance of CMP Model in the ORC verification method 300 to identify the real hotspots on wafer is discussed. Wafer data comparison showing the improvement in predicting real process window limiter in comparison with the standard flow is shown. Necessities of co-optimized development with DFM/Litho/OPC/CMP for advanced technology nodes are projected. Limitation and improvements scope for more accurate prediction of lithography hotspots is stressed. Mask critical dimension uniformity (CDU) signature extraction due to topography and pattern density related etch effects identification are some of the further extension of this work.

Dishing is defined as a difference between the height of a feature (e.g., copper interconnect and silicon dioxide shallow trench isolation (STI)) in a trench and that of a dielectric layer in spaces surrounding the trench. Dishing can be positive if the feature in the trench is lower than the neighboring dielectric layer or can be negative if the feature sticks up above the neighboring dielectric layer. Erosion is defined as a difference between the thicknesses of the dielectric layer before and after CMP. Hence, erosion is the loss in the thickness of the dielectric layer during CMP and is always positive. The sum of dishing and erosion gives the feature thickness loss (also known as the copper thinning effect) during CMP. Dishing and erosion depend on layout patterns (e.g., interconnect width and space, and pattern density), polishing (e.g., CMP) process settings (e.g., down force, table speed, and slurry flow rate), over-polishing time, and so on. In addition, dishing and erosion on metal level one could lead to increased dishing and erosion and, therefore, more non-uniformed wafer surface on metal level two.

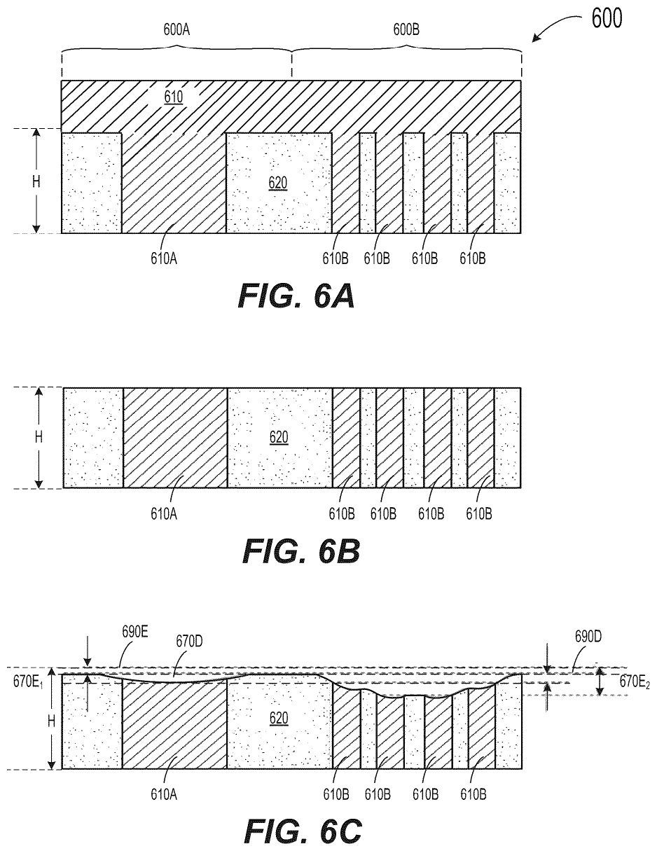

FIG. 6A illustrates an intermediate step of a method of fabricating a semiconductor structure 600 after a conductive material 610 (such as metal, e.g., copper (Cu), tungsten (W), or some other suitable metal) is deposited to fill spaces surrounded by a dielectric material 620 that is in height (or thickness) H and planarized to form first and second metal lines 610A and 610B. As shown in FIG. 6A, the semiconductor structure 600 can be divided into a first (isolated) region 600A and a second (dense) region 600B, within which the second metal lines 610B have a denser pattern density than the first metal lines 610A formed within the isolated region 600A. Following the deposition of the conductive material 610, a planarization process, e.g., CMP process, can be performed to polish and planarize the surface of the semiconductor structure 600 down to the dielectric material 620 to remove the overburden portion of the conductive material 610. Ideally, after the CMP process the semiconductor structure 600 would have a uniform or even wafer topology and both the conductive material 610 (i.e., the first and second metal lines 610A and 610B) and the dielectric material 620 of the semiconductor structure 600 would be in height H, as shown in FIG. 6B. However, the conductive material 610 and the dielectric material 620 may be polished at different polishing rates during CMP process due to the difference in their hardness and pattern densities, and, as a result, the surface of the semiconductor structure 600 may be non-uniformed or uneven, which is caused by CMP due to erosion and dishing as a result of iso-dense bias.

The loading effect of CMP process will polish dense features, e.g., the second metal lines 610B within the dense region 600B, at different polishing rates than isolated features, e.g., the first metal lines 610A within the isolated region 600A. Therefore, the second metal lines 610B and a portion of the dielectric material 620 within the dense region 600B will be polished and removed more during CMP process than the first metal lines 610A and the remaining of the dielectric material 620 within the isolated region 600A, and, as a result, erosion occurs, creating a first erosion cavity 670E₁ within the isolated region 600A and a second erosion cavity 670E₂ within the dense region 600B compared to an ideal surface represented by a non-erosion line 690E, the second erosion cavity 670E₂ being larger and deeper than the first erosion cavity 670E₁, as shown in FIG. 6C. During CMP process, excessive copper may be polished and removed from the first metal lines 610A and the second metal lines 610B due to dishing. For example, excessive copper may be polished and removed from the first metal lines 610A, and, as a result, dishing occurs, creating a dishing cavity 670D compared to an ideal surface represented by a non-dishing line 690D and reducing the effective thickness of the first metal lines 610A.

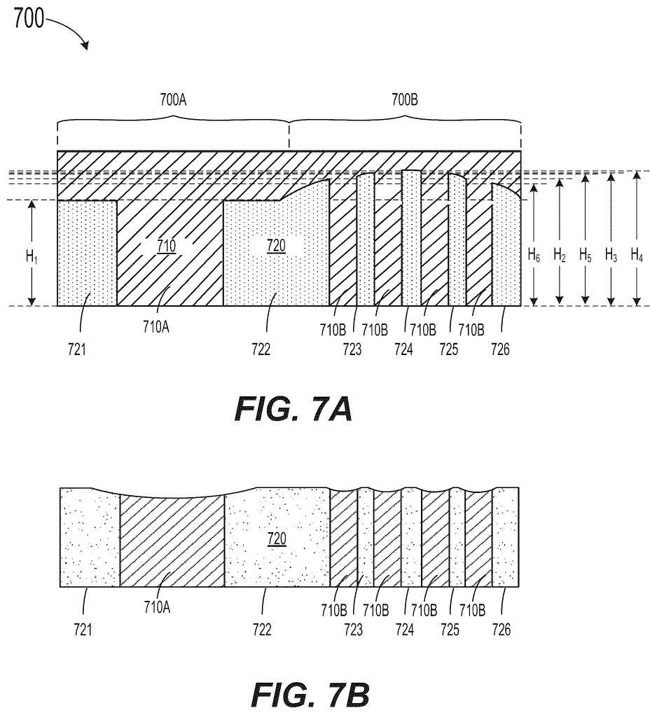

To address the above-mentioned issues, e.g., erosion, aspects of the present disclosure disclose methods for patterning for CMP iso-dense bias compensation using z-height. FIG. 7A illustrates an intermediate step of an exemplary method of fabricating a semiconductor structure 700 after a conductive material 710 (such as metal, e.g., copper, tungsten, or some other suitable metal) is deposited to fill spaces surrounded by a dielectric material 720 and planarized to form first and second metal lines 710A and 710B according to some embodiments of the present disclosure. The exemplary method can be implemented by a wafer processing system. As shown in FIG. 7A, the semiconductor structure 700 can also be divided into a first (isolated) region 700A and a second (dense) region 700B, within which the second metal lines 710B have a denser pattern density than the first metal lines 710A formed within the isolated region 700A.

The exemplary method illustrated in FIG. 7A differs from the method illustrated in FIG. 6A in that the dielectric material 720 (e.g., including first to sixth dielectric layers 721-726 formed) can vary in height (or thickness) in different regions based on their pattern densities (or iso-dense bias) in order to compensate the copper thinning effect caused by CMP due to dishing and erosion as a result of iso-dense bias. In an embodiment, first one or more of the first to sixth dielectric layers 721-726 within a first region that has a denser pattern density than a second region can be formed taller than second one or more of the first to sixth dielectric layers 721-726 within the second region. For example, the first dielectric layer 721 and any one of the second to sixth dielectric layers 722-726 are within the isolated region 700A and the dense region 700B, respectively, which has a dense pattern density than the isolated region 700A, and, therefore, any one of the second to sixth dielectric layers 722-726 (e.g., in heights (or thicknesses) H₂ to H₆, respectively) is formed taller than the first dielectric layer 721 (e.g., in height (or thickness) H₁) in order to compensate the more severe copper thinning effect caused by CMP within the dense region 700B due to dishing and erosion as a result of iso-dense bias.

In another embodiment, a first one of one or more of the first to sixth dielectric layers 721-726 that are within the same region (e.g., the isolated region 700A or the dense region 700B) can be formed taller than a second one if the first one is closer than the second one to a center of the region. For example, within the dense region 700B the fourth dielectric layer 724 is closer to the center of the dense region 700B than the third and fifth dielectric layers 723 and 725 than the second and sixth dielectric layers 722 and 726, and, therefore, is formed (e.g., in height H₄) taller than the third and fifth dielectric layers 723 and 725 (e.g., in heights H₃ and H₅, respectively) than the second and sixth dielectric layers 722 and 726 (e.g., in heights H₂ and H₆, respectively) in order to compensate the more severe copper thinning effect caused by CMP around the center of the dense region 700B due to dishing and erosion as a result of iso-dense bias.

In some embodiments, any one of the second to sixth dielectric layers 722-726, which are within the dense region 700B, can be formed to have a varied height (or an inclined top surface) that increases toward the center of the dense region 700B. For example, as shown in FIG. 7A the second and third dielectric layers 722 and 723 are formed taller at right side than at left side, while the fifth and sixth dielectric layers 725 and 726 are formed taller at left side than at right side.

Following the CMP iso-dense bias compensation using z-height on a portion of the dielectric material 720 that is within the dense region 700B (i.e., the second to sixth dielectric layers 722-726) in order to compensate the copper thinning effect caused by CMP due to dishing and erosion as a result of iso-dense bias, the conductive material 710 can be deposited to fill spaces surrounded by the dielectric material 720 (i.e., the first to sixth dielectric layers 721-726) and planarized to form the first and second metal lines 710A and 710B. As the dielectric material 720 (e.g., the second to sixth dielectric layers 722-726) and thus the second metal lines 710B within the dense region 700B are compensated with respect to their heights, i.e., offsetting their heights prior to CMP, and, therefore, the copper thinning effect (e.g., erosion) caused by CMP as a result of iso-dense bias can be mitigated, the semiconductor structure 700 may have a more uniform or evener wafer topology (or surface) within the dense region 700B, as shown in FIG. 7B, as compared with the semiconductor structure 600 within the dense region 600B shown in FIG. 6C.

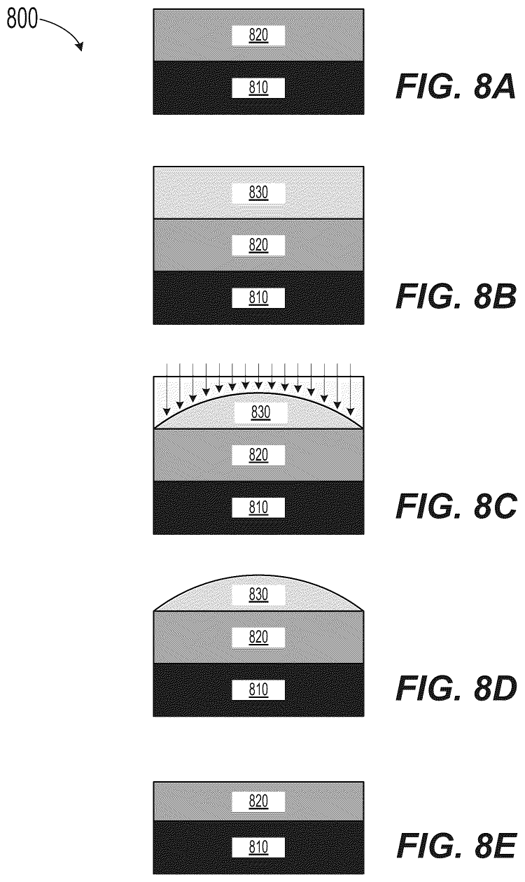

FIGS. 8A-8E illustrate intermediate steps of an exemplary method of fabricating a semiconductor structure 800 according to some embodiments of the present disclosure. In an embodiment, a dielectric layer, e.g., the second to sixth dielectric layers 722-726, may have its height compensated based on iso-dense bias. The exemplary method can be implemented by a wafer processing system. As shown in FIG. 8A, a substrate 810, e.g., Si or Ge substrate, can be provided, and a layer, e.g., a spin-on-glass (SOG) layer 820 (e.g., a lower portion of the dielectric material 720 below height H₁) can be formed on the substrate 810. As shown in FIG. 8B, a height correction layer (or film) 830 (e.g., an upper portion of the dielectric material 720 above height H₁) can be formed on the SOG layer 820. As shown in FIG. 8C, the height correction layer 830 can be exposed with radiation or heat based on a pattern density of a region within which the height correction layer 830 (i.e., a dielectric layer located under the height correction layer 830, e.g., the lower portions of the second to sixth dielectric layers 722-726 below height H₁) is located. As shown in FIG. 8D, the exposed height correction layer 830 can be baked and developed to form a final height correction film 830 (e.g., the upper portions of the second to sixth dielectric layers 722-726 above height H₁) that compensates and offsets the height of the dielectric layer (e.g., the lower portions of the second to sixth dielectric layers 722-726 below height H₁) located thereunder prior to CMP in order to mitigate the copper thinning effect (e.g., the erosion) caused by CMP as a result of iso-dense bias. As shown in FIG. 8E, the height correction layer 830 and the SOG layer 820 (that form a final dielectric layer, e.g., the second to sixth dielectric layers 722-726) can be polished by CMP to form a polished SOG layer 820. As the final dielectric material and thus one or more metal lines that fill trenches surrounded by the final dielectric layer are compensated with respect to their heights, i.e., offsetting their heights prior to CMP, and, therefore, the copper thinning effect (e.g., erosion) caused by CMP as a result of iso-dense bias can be mitigated, the semiconductor structure 800 thus may have a uniform or even wafer topology.

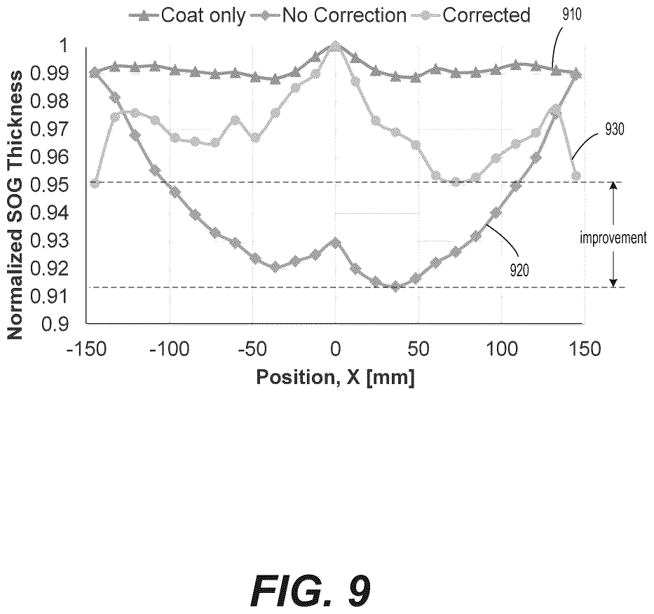

FIG. 9 shows the thicknesses (uniformness) across a surface (e.g., measured in X axis) of three different dielectric layers (e.g., the SOG layer 820 shown in FIG. 8E) prior to and after CMP. A first line 910 with triangular dots represents a dielectric layer (e.g., the SOG layer 820) coated with a height correction layer (e.g., the height correction layer 830) that is not corrected yet with respect to its height, as shown in FIG. 8B. A second line 920 with rectangular dots represents the dielectric layer coated with the height correction layer after CMP, which is not corrected yet with respect to its height prior to CMP. As shown, the dielectric layer represented by the second line 920 has smaller thicknesses around the origin (i.e., 0 mm) and larger thicknesses away from the origin (e.g., at ±50, 100 and 150 mm), and the closer the dielectric layer is located to the origin the shorter the dielectric layer becomes, which corresponds to the dielectric material 620 shown in FIG. 6C. A third line 930 with round dots represents the dielectric layer coated with the height correction layer 830 after CMP, which is corrected with respect to its height prior to CMP. As shown, the dielectric layer represented by the third line 930 has a very large portion (e.g., from −125 mm to 125mm) that is taller than the dielectric layer represented by the second line 920 and has a larger total thickness mean and a smaller total thick variance (TTV) than the dielectric layer represented by the second line 920. Therefore, the dielectric layer represented by the third line 930 suffers less copper thinning effect and is more uniform or even than the dielectric layer represented by the second line 920. As shown in FIG. 9, a significant improvement of the thickness of the dielectric layer can be achieved if the height correction layer is formed and corrected with respect to its height based on the pattern density of a region within which the dielectric layer is formed.

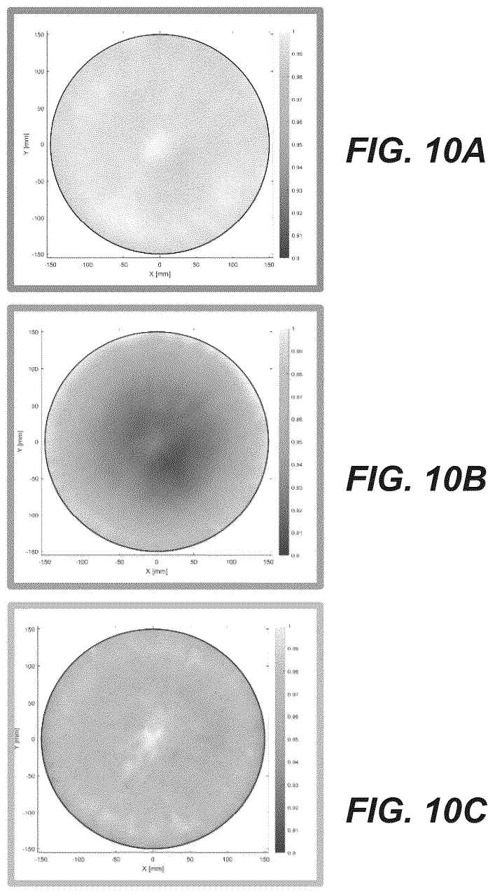

FIGS. 10A and 10B show the topologies of a semiconductor structure that includes one or more dielectric layers (e.g., the dielectric layers represented by the first and second lines 910 and 920 shown in FIG. 9) coated with a height correction layer that is not corrected with respect to its height prior to and after CMP, respectively. FIG. 10C shows the topology of a semiconductor structure that includes one or more dielectric layers (e.g., the dielectric layer represented by the third line 930 shown in FIG. 9) coated with a height correction layer (e.g., the height correction layer 830) that is corrected with respect to its height based on the pattern density or topography of a region within which the dielectric layers are located after CMP. By comparing FIGS. 10B and 10C, it is found that the semiconductor structure that corresponds to FIG. 10C has more uniform or evener topology than the semiconductor structure that corresponds to FIG. 10B.

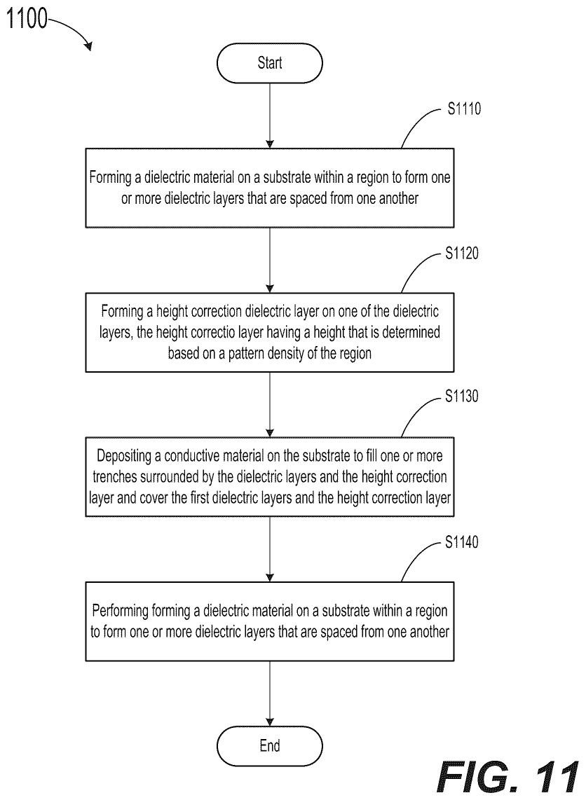

FIG. 11 is a flow chart of an exemplary method 1100 for patterning for CMP iso-dense bias compensation using z-height to a semiconductor structure, e.g., the semiconductor structure 700, according to some embodiments of the present disclosure. In various embodiments, some of the steps of the method 1100 shown can be performed concurrently or in a different order than shown, can be substituted by other method steps, or can be omitted. Additional method steps can also be performed as desired. Aspects of the method 1100 can be implemented by a wafer processing system. The method 1100 starts with step S1110, at which a substrate can be provided, and a dielectric material can be formed on the substrate within a first region to form one or more first dielectric layers that are spaced from one another. For example, the dielectric material 720 can be formed on a substrate within the dense region 700B to form the second to sixth dielectric layers 722-726 (i.e., a lower portion of the second to sixth dielectric layers 722-726 below the height H₁), which are spaced from one another, as shown in FIG. 7A. The method 1100 can proceed to step S1120.

At step S1120, a first height correction layer can be formed on a first one of the first dielectric layers, the first height correction layer having a first height that is determined based on a first pattern density of the first region. For example, the height correction layer 830 (i.e., an upper portion of the second to sixth dielectric layer 722-726 above the height H₁) can be formed on the lower portion of the third dielectric layer 723 below the height H₁, the height correction layer 830 having a first height that is determined based on a first pattern density of the dense region 700B, as shown in FIGS. 7A and 8D. In an embodiment, the first height of the first height correction layer can be varied and increase toward a center of the first region. For example, the height H of the lower and upper portions of the third dielectric layer 723 varies and increases toward the center of the dense region 700B, as shown in FIG. 7A. The method 1100 can proceed to step S1130.

At step S1130, a conductive material can be deposited on the substrate to fill one or more first trenches surrounded by the first dielectric layers and the first height correction layer and cover the first dielectric layers and the first height correction layer. For example, the conductive material 710 can be deposited on the substrate to fill one or more first trenches surrounded by the lower and upper portions of the second to sixth dielectric layers and cover the lower and upper portions of the second to sixth dielectric layers 722-726, as shown in FIG. 7A. The method 1100 can proceed to step S1140.

At step S1140, a planarization process can be performed to planarize the conductive material and the first height correction layer until uncovering the first dielectric layers. For example, the planarization process can be performed to planarize the conductive material 710 and the upper portion of the third dielectric layer 723 above the height H₁, as shown in FIG. 7B. In an embodiment, the conductive material and the first height correction layer can be polished when the planarization process is performed. For example, the planarization process can be a chemical-mechanical polishing/planarization (CMP) process.

In an embodiment, the method 1100 can further include a step of forming a second height correction layer on a second one of the first dielectric layers, the second one of the first dielectric layers being closer than the first one of the first dielectric layers to a center of the first region and having a second height that is greater than the first height of the first one of the first dielectric layers. For example, another height correction layer (i.e., an upper portion of the second to sixth dielectric layer 722-726 above the height H₁) can be formed on the lower portion of the fourth dielectric layer 724 below the height H₁, the fourth dielectric layer 724 being closer than the third dielectric layer 723 to a center of the dense region 700B and the another height correction layer being taller than the height correction layer 830.

In another embodiment, the method 1100 can also include a step of forming the dielectric material on the substrate within a second region to form one or more second dielectric layers that are spaced from one another, depositing the conductive material on the substrate to fill one or more second trenches surrounded by the second dielectric layers and cover the second dielectric layers, and performing the planarization process to planarize the conductive material until uncovering the second dielectric layers, wherein the first pattern density is greater than a second pattern density of the second region. In some embodiments, the method 1100 can also include a step of forming a second height correction layer on one of the second dielectric layers, the second height correction layer having a second height that is determined based on the second pattern density of the second region, the second height being less than the first height, wherein depositing the conductive material on the substrate to fill the second trenches surrounded by the second dielectric layers and cover the second dielectric layers includes depositing the conductive material on the substrate to fill the second trenches surrounded by the second dielectric layers and the second height correction layer and cover the second dielectric layers and the second height correction layer, and performing the planarization process to planarize the conductive material until uncovering the second dielectric layers includes performing the planarization process to planarize the conductive material and the second height correction layer until uncovering the second dielectric layers. For example, the dielectric material 720 can also be formed on the substrate within the isolated region 700A to form the first dielectric layer 721, the conductive material 710 can also be deposited on the substrate to fill the trench surrounded by the first dielectric layer 721, and the planarization process can be performed to planarize the conductive material 710 until uncovering the first dielectric layer 721, wherein the pattern density of the dense region is greater than the pattern density of the isolated region.

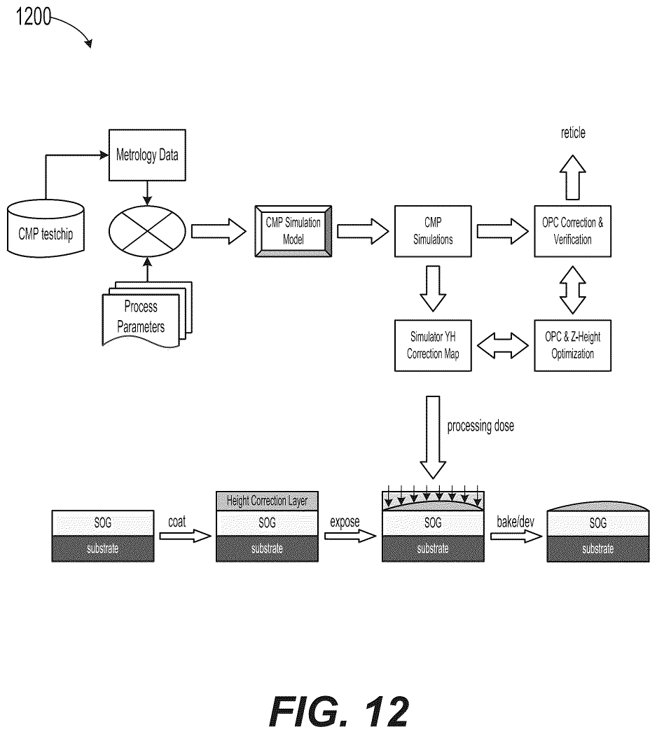

FIG. 12 shows a system 1200 that combines the CMP model simulation flow 100, the topography aware OPC Verification method 300, the intermediate steps of the exemplary method of fabricating the semiconductor structure 800 and the exemplary method 1100 for patterning for CMP iso-dense bias compensation using z-height to a semiconductor structure, e.g., the semiconductor structure 700, according to some embodiments of the present disclosure. As shown, a height correction layer (e.g., the height correction layer 830) can be processed with a processing dose, e.g., exposed with radiation or heat, based on a pattern density of a region within which the height correction layer is located. In an embodiment, the radiation or heat can be adjusted based on the global and/or local topography variations (or z-height) of the wafer output from the CMP model simulation flow 100.

In the preceding description, specific details have been set forth, such as a particular geometry of a processing system and descriptions of various components and processes used therein. It should be understood, however, that techniques herein may be practiced in other embodiments that depart from these specific details, and that such details are for purposes of explanation and not limitation. Embodiments disclosed herein have been described with reference to the accompanying drawings. Similarly, for purposes of explanation, specific numbers, materials, and configurations have been set forth in order to provide a thorough understanding. Nevertheless, embodiments may be practiced without such specific details. Components having substantially the same functional constructions are denoted by like reference characters, and thus any redundant descriptions may be omitted.

Various techniques have been described as multiple discrete operations to assist in understanding the various embodiments. The order of description should not be construed as to imply that these operations are necessarily order dependent. Indeed, these operations need not be performed in the order of presentation. Operations described may be performed in a different order than the described embodiment. Various additional operations may be performed and/or described operations may be omitted in additional embodiments.

“Substrate” or “target substrate” as used herein generically refers to an object being processed in accordance with the present disclosure. The substrate may include any material portion or structure of a device, particularly a semiconductor or other electronics device, and may, for example, be a base substrate structure, such as a semiconductor wafer, reticle, or a dielectric layer on or overlying a base substrate structure such as a thin film. Thus, substrate is not limited to any particular base structure, underlying dielectric layer or overlying dielectric layer, patterned or un-patterned, but rather, is contemplated to include any such dielectric layer or base structure, and any combination of dielectric layers and/or base structures. The description may reference particular types of substrates, but this is for illustrative purposes only.

Those skilled in the art will also understand that there can be many variations made to the operations of the techniques explained above while still achieving the same objectives of the present disclosure. Such variations are intended to be covered by the scope of this disclosure. As such, the foregoing descriptions of embodiments of the invention are not intended to be limiting. Rather, any limitations to embodiments of the invention are presented in the following claims.

What is claimed is:

1. A method of semiconductor processing, comprising:
providing a nominal condition for a substrate;
updating the nominal condition based on topography of the substrate;
determining a process window (PW) condition based on the updated nominal condition;
performing nominal and PW simulations based on the updated nominal and PW conditions; and
performing optical proximity correction (OPC) verification checks at the updated nominal and PW conditions to identify hotspots of the substrate.

2. The method of claim 1, further comprising:
calculating topography induced focus shift based on the topography of the substrate,
wherein the nominal condition includes a nominal focus maintained in a lithography process, and updating the nominal condition includes adding the topography induced focus shift to the nominal condition.

3. The method of claim 1, further comprising:
performing a topography simulation across the substrate to calculate the topography of the substrate.

4. The method of claim 1, wherein the nominal condition includes a nominal dose, and the PW condition includes variations in dose relative to the nominal dose.

5. The method of claim 1, wherein the nominal condition includes a nominal focus, and the PW condition includes a PW focus relative to the nominal focus.

6. The method of claim 1, wherein the nominal condition includes a nominal mask bias, and the PW condition includes a mask bias offset relative to the nominal mask bias.

7. The method of claim 1, further comprising:
forming a dielectric material on the substrate within a first region to form one or more first dielectric layers that are spaced from one another;
forming a first height correction layer on a first one of the first dielectric layers, the first height correction layer having a first height that is determined based on the topography of the substrate within the first region;
depositing a conductive material on the substrate to fill one or more first trenches surrounded by the first dielectric layers and the first height correction layer and cover the first dielectric layers and the first height correction layer; and
performing a planarization process to planarize the conductive material and the first height correction layer until uncovering the first dielectric layers.

8. The method of claim 7, further comprising:
forming a second height correction layer on a second one of the first dielectric layers, the second one of the first dielectric layers being closer than the first one of the first dielectric layers to a center of the first region and having a second height that is greater than the first height of the first one of the first dielectric layers.

9. The method of claim 7, wherein the first height of the first height correction layer is varied and increases toward a center of the first region.

10. The method of claim 7, further comprising:
forming the dielectric material on the substrate within a second region to form one or more second dielectric layers that are spaced from one another;
depositing the conductive material on the substrate to fill one or more second trenches surrounded by the second dielectric layers and cover the second dielectric layers; and
performing the planarization process to planarize the conductive material until uncovering the second dielectric layers,
wherein the topography of the substrate within the second region is different from the topography of the substrate within the first region.

11. The method of claim 10, further comprising:
forming a second height correction layer on one of the second dielectric layers, the second height correction layer having a second height that is determined based on the topography of the substrate within the second region, the second height being different from the first height,
wherein depositing the conductive material on the substrate to fill the second trenches surrounded by the second dielectric layers and cover the second dielectric layers includes depositing the conductive material on the substrate to fill the second trenches surrounded by the second dielectric layers and the second height correction layer and cover the second dielectric layers and the second height correction layer, and
performing the planarization process to planarize the conductive material until uncovering the second dielectric layers includes performing the planarization process to planarize the conductive material and the second height correction layer until uncovering the second dielectric layers.

12. The method of claim 7, wherein the conductive material and the first height correction layer are polished when the planarization process is performed.

13. The method of claim 12, wherein the planarization process is a chemical-mechanical polishing/planarization (CMP) process.

14. The method of claim 7, wherein the conductive material includes cupper (Cu).

15. The method of claim 7, wherein the conductive material includes tungsten (W).

16. The method of claim 7, wherein the dielectric material is formed on the substrate in a spin-on film deposition process.
